(19) United States
(12) Patent Application Publication
(10) Pub. No.: US 2007/0007854 A1
(43) Pub. Date: Jan. 11, 2007

(54) Ripple free tunable capacitor and method of operation and manufacture therefore

(76) Inventors: James Oakes, Sudbury, MA (US); Nicolaas Du Toit, Columbia, MD (US); Louise C. Sengupta, Ellicott City, MD (US); Richard C. Eden, Briarcliff, TX (US)

Correspondence Address: James S. Finn;C/O William Tucker, 14431 Goliad Dr., Box #8, Malakoff, TX, 75148, US

(21) Appl. No.: 11/246,768

(22) Filed: Oct. 7, 2005

Related U.S. Application Data
(63) Continuation-in-part of application No. 11/178,041, filed on Jul. 9, 2005.

(51) Int. Cl. H01L 41/00

(52) U.S. Cl. 310/315

(57) ABSTRACT

An embodiment of the present invention provides an apparatus, comprising a voltage tunable capacitor including a substrate, wherein a surface of the substrate opposite the voltage tunable capacitor is made physically rough such that reflections off a surface internal to the substrate are scattered and dissipated. The surface of the substrate opposite the voltage tunable capacitor may be made physically rough by using abrasion or other mechanical techniques or may be made physically rough by creating a rough surface through deposition of a material on the surface in a non-uniform manner such as evaporating a rough metal or dielectric. Further, the surface of the substrate opposite the voltage tunable capacitor may be made physically rough by plating metals under what would otherwise be considered a poor plating condition leading to a rough surface.

### CROSS REFERENCED TO RELATED APPLICATIONS

This application is a continuation in part of application Ser. No. 11/178,041 entitled “AN APPARATUS AND METHOD CAPABLE OF A HIGH FUNDAMENTAL ACOUSTIC RESONANCE FREQUENCY AND A WIDE RESONANCE-FREE FREQUENCY RANGE, filed Jul. 9, 2005.

### BACKGROUND OF THE INVENTION

Varactors are voltage tunable capacitors in which the capacitance is dependent on a voltage applied thereto. Although not limited in this respect, this property has applications in electrically tuning radio frequency (RF) circuits, such as filters, phase shifters, and so on. The most commonly used varactor is a semiconductor diode varactor, which has the advantages of high tunability and low tuning voltage, but suffers low Q, low power handling capability, and limited capacitance range. A new type of varactor is a ferroelectric varactor in which the capacitance is tuned by varying the dielectric constant of a ferroelectric material by changing the bias voltage. Ferroelectric varactors have high Q, high power handling capacity, and high capacitance range.

One ferroelectric varactor is disclosed in U.S. Pat. No. 5,640,042 entitled “Thin Film Ferroelectric Varactor” by Thomas E. Koscica et al. That patent discloses a planar ferroelectric varactor, which includes a carrier substrate layer, a high temperature superconducting metallic layer deposited on the substrate, a lattice matching, a thin film ferroelectric layer deposited on the metallic layer, and a plurality of metallic conductors disposed on the ferroelectric layer and in contact with radio frequency (RF) transmission lines in tuning devices. Another tunable capacitor using a ferroelectric element in combination with a superconducting element is disclosed in U.S. Pat. No. 5,721,194. Tunable varactors that utilize a ferroelectric layer, and various devices that include such varactors are also disclosed in U.S. Pat. No. 6,531,936, entitled “Voltage Tunable Varactors And Tunable Devices Including Such Varactors,” filed Oct. 15, 1999, and assigned to the same assignee as the present invention.

A major concern in tunable capacitors including voltage tunable dielectric capacitors is the elimination of losses due to the electrostrictive effect and acoustic resonances. These resonances typically manifest as a series of bumps and ripples on the Q vs. Frequency characteristic of a tunable capacitor causing the Q-factor to dip as low as 10 to 20.

A model of dielectric losses due to the electrostrictive effect and acoustic resonances has been proposed with Electrostrictive resonances in Ba0_{.7}Sr0_{.3}.TiO₃ thin films at microwave frequencies which uses very thin BST layers, which would ensure a sufficiently high fundamental frequency of the acoustic resonance—i.e. beyond the frequency range of the application.

Tunable capacitors using BST (Barium Strontium Titanate) or other related materials suffer from ripples in the effective series resistance (ESR) of the capacitors over frequency. This is due to acoustic resonances in the substrate that are coupled into the electrical domain due to the electrostrictive nature of the Parascan® Tunable Capacitors (PTC) voltage tunable material. These ripples or resonances in the ESR are manifest in the electrical response of circuits including filters which use the tunable capacitors.

Previously, the ripples in the circuit response had to be accepted as an outcome of using the tunable capacitors, although the effects could be reduced if PTC's with high value capacitance, typically above 10 pF could be avoided at frequencies below 1 GHz. However, avoiding high value capacitance at frequencies below 1 GHz places a severe limitation on the range of applications for PTC's. Many circuits exhibited the problem. Thus, a strong need exists for a ripple free tunable capacitor and method of operation and manufacture therefore.

### SUMMARY OF THE INVENTION

An embodiment of the present invention provides an apparatus, comprising a voltage tunable capacitor including a substrate, wherein a surface of the substrate opposite the voltage tunable capacitor is made physically rough such that reflections off a surface internal to the substrate are scattered and dissipated. The surface of the substrate opposite the voltage tunable capacitor may be made physically rough by using abrasion or other mechanical techniques or may be made physically rough by creating a rough surface through deposition of a material on the surface in a non-uniform manner such as evaporating a rough metal or dielectric. Further, the surface of the substrate opposite the voltage tunable capacitor may be made physically rough by plating metals under what would otherwise be considered a poor plating condition leading to a rough surface.

The voltage tunable capacitor may be made tunable by using a Parascan® voltage tunable dielectric material and may comprise a bottom electrode layer adjacent the substrate; a voltage tunable dielectric layer adjacent the bottom electrode layer, the voltage tunable dielectric layer including an active region; a top electrode adjacent the voltage tunable dielectric layer; a final interconnect layer connected to the top electrode via an interlayer; and wherein the top and bottom electrodes are at a predetermined thickness such that a desired high fundamental acoustic resonance is obtained.

An embodiment of the present invention may also provide a method of reducing ripples in a voltage tunable capacitor, comprising making a surface of a substrate opposite the voltage tunable capacitor physically rough such that reflections off a surface internal to the substrate are scattered and dissipated.

Another embodiment of the present invention provides a method of manufacturing a voltage tunable capacitor with reduced ripples, comprising manufacturing a surface of a substrate opposite the voltage tunable capacitor physically rough such that reflections off a surface internal to the substrate are scattered and dissipated.

### BRIEF DESCRIPTION OF THE DRAWINGS

The present invention is described with reference to the accompanying drawings. In the drawings, like reference numbers indicate identical or functionally similar elements. Additionally, the left-most digit(s) of a reference number identifies the drawing in which the reference number first appears.

FIG. 1 illustrates a cross-sectional view of a tunable capacitor structure of one embodiment of the present invention without the physically rough surface;

FIG. 2 illustrates a cross-sectional view of a tunable capacitor structure of one embodiment of the present invention with the physically rough surface of one embodiment of the present invention;

FIG. 3 shows a filter response at 5 V bias of PLD deposited Tunable Film on MgO (a) before and (b) after roughening of backside of MgO;

FIG. 4 shows a filter response at 15 V bias of PLD deposited tunable film on MgO (a) before and (b) after roughening of backside of MgO;

FIG. 5 illustrates the filter response at 35 V bias of PLD deposited tunable film on MgO (a) before and (b) after roughening of backside of MgO;

FIG. 6 illustrates the filter response at 5 V bias of PLD deposited tunable film on alumina (a) before and (b) after roughening of backside of alumina;

FIG. 7 provides a filter response at ˜15 V bias of PLD deposited tunable film on alumina (a) before and (b) after roughening of backside of alumina;

FIG. 8 provides the filter response at ˜35 V bias of PLD deposited tunable film on alumina (a) before and (b) after roughening of backside of alumina;

FIG. 9 provides filter response at ˜45 V bias of PLD deposited tunable film on alumina (a) before and (b) after roughening of backside of alumina;

FIG. 10 provides the filter response at ˜5 V bias of RF sputtered tunable film on alumina (b) before and (b) after roughening of backside of alumina;

FIG. 11 provides the filter response at ˜15 V bias of RF sputtered tunable film on alumina before and (b) after roughening of backside of alumina;

FIG. 12 graphically depicts the ESR of PLD deposited tunable film on MgO before and after roughening of the backside of MgO at 0 and 50 V of one embodiment of the present invention; and

FIG. 13 graphically depicts a simulation of ESR of PLD deposited tunable film on MgO before and after roughening of backside of MgO at 50 V.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

An embodiment of the present invention provides that the surface of a substrate opposite a Parascan tunable capacitor (PTC) be made physically rough such that reflections off that surface internal to the substrate may be scattered and dissipated. With the ripple effect removed, the limitations on the use of the PTC as stated above, no longer apply. This method has no limitations in terms of formulations of the voltage tunable material, configurations of the PTC, or substrate materials.

In some embodiments of the present invention and not limited in this respect, making the substrate may be made physically rough by using abrasion or other mechanical means or by creating a rough surface through deposition of a material on the surface in a non-uniform manner such as evaporating a rough metal or dielectric or plating metals under what would otherwise be considered a poor plating condition leading to a rough surface. Again, these illustrative examples of techniques to make the substrate rough are merely examples and provided for completeness of disclosure and the present invention is not meant to be limited to these techniques.

The ESR resonances impacted may be at low frequencies if the resonant part of the tunable capacitor is acoustically large or at microwave frequencies above 1 GHz for fine structures in the tunable capacitor.

The present invention may utilize modeling techniques provided in parent patent application referenced above which provides a method of modeling electrostrictive effect and acoustic resonances that facilitates the design of arbitrary circuits in the acoustic domain of the PTC structure and may include the following:

Step 1. It is assumed that an electrostrictive effect causes a small amount of RF energy to be converted into acoustic energy, which exists within the entire PTC structure as bulk acoustic waves traveling in the two directions perpendicular to the BST layer. These waves are modeled as equivalent electrical waves existing in transmission lines with characteristic impedances and complex propagation constants typically derived.

Step 2. The characteristic impedances and complex propagation constants are adjusted empirically to account for actual process variations in manufacturing of the tunable capacitors;

Step 3. The characteristic impedances and complex propagation constants are adjusted empirically to account for end-effects in the directions transversal to the wave direction, viz. layers extending further than the active area (such as the substrate) and layers not completely covering the entire active area (such as the final interconnect layer).

Step 4. The electrostrictive effect, i.e. the transducer mechanism that links the electrical and acoustic domains, is modeled by dividing the BST layer into thin layers or slices—each slice's thickness representing a small fraction of an acoustic wavelength—and injecting at each junction between slices, an acoustic “current” proportional to the electrical current through the tunable capacitor. The real part of the vector sum of acoustic “voltages” at all slice junctions, divided by the electrical current vector, is taken to be representative of (proportional to) that part of the tunable capacitor effective series resistance (ESR) contributed by the electrostrictive effect and acoustic resonances. This method of modeling recognizes the fact that the BST layer has insignificant thickness in terms of electrical wavelengths, while having appreciable thickness in terms of acoustic wavelengths.

Table 1 illustrates the range of acoustic parameters that were found to provide repeatable modeling of the ESR for various PTC designs, although it is understood that the present invention is not limited in this respect nor limited to the below values, parameters or materials.

TABLE 1
Ranges of Acoustic Parameters used in Modeling of ESR

| Material | Parameter | Units | Min value | Max value | Comment |
|---|---|---|---|---|---|
| MgO | Velocity of sound | m/s | 6,000 | 10,000 | Substrate |
| | Characteristic impedance | Ohm | 13,000 | 35,000 | Substrate |
| | Attenuation per wavelength | dB | 0 | 5 | Substrate |
| Al₂O₃ | Velocity of sound | m/s | 8,000 | 12,000 | Substrate |
| | Characteristic impedance | Ohm | 17,000 | 45,000 | Substrate |
| | Attenuation per wavelength | dB | 0 | 5 | Substrate |
| Pt | Velocity of sound | m/s | 3,000 | 4,000 | Electrode |
| | Characteristic impedance | Ohm | 65,000 | 75,000 | Electrode |
| | Attenuation per wavelength | dB | 0 | 2 | Electrode |
| BST | Velocity of sound | m/s | 4,000 | 10,000 | Active layer |
| | Characteristic impedance | Ohm | 40,000 | 60,000 | Active layer |
| | Attenuation per wavelength | dB | 0 | 2 | Active layer |
| Ti | Velocity of sound | m/s | 4,000 | 5,000 | Interlayer |
| | Characteristic impedance | Ohm | 4,000 | 70,000 | Interlayer |
| | Attenuation per wavelength | dB | 0 | 2 | Interlayer |
| Au | Velocity of sound | m/s | 2,500 | 3,000 | Interconnect |
| | Characteristic impedance | Ohm | 14,000 | 70,000 | Interconnect |
| | Attenuation per wavelength | dB | 0 | 2 | Interconnect |

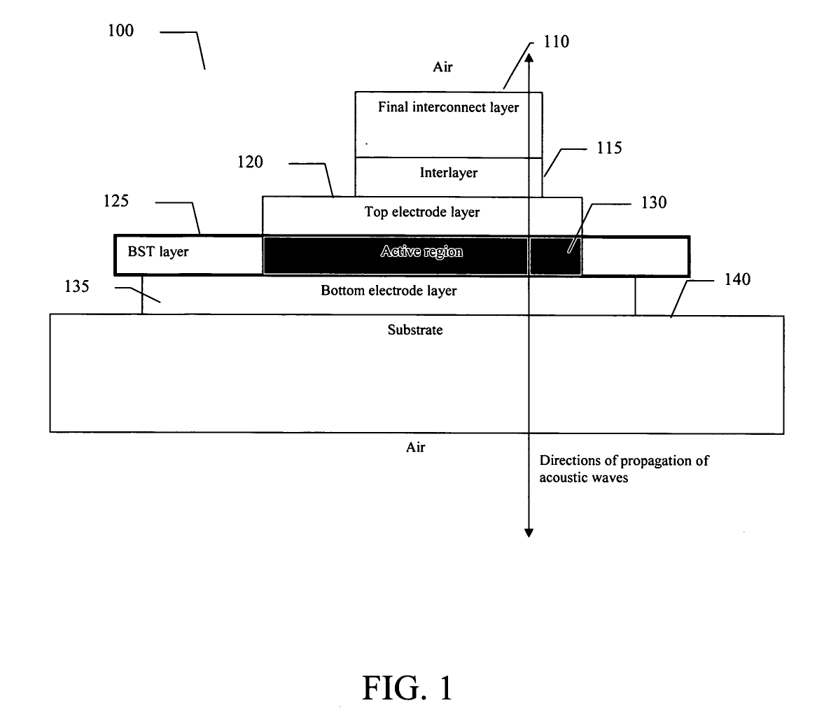

Turning now to the figures, FIG. 1, shown generally as 100, is a cross-sectional view of a tunable capacitor structure prior to the substrate being made rough. The top 120 and bottom 135 electrodes may be made sufficiently thin and residing on substrate 140 such that a sufficiently high fundamental acoustic resonance is obtained. As an optional further refinement when applicable, the tunable capacitor may be designed such that the interlayer 115 and final interconnect layer 110 cover only a small fraction of the active region 130 of BST layer 125, thereby reducing the amplitude of resonances due to the interlayer 115 or final interconnect layer 110. The interlayer 115 and final interconnect layer 110 thickness and material properties may therefore be unimportant. As an optional further refinement when applicable, the substrate may be chosen to have a high acoustic loss factor, Al₂O₃ being a better choice than MgO, thereby reducing the amplitude of resonances due to the substrate layer 140. The substrate layer 140 thickness is unimportant. In a preferred embodiment of this design, a 300 nm thick BST layer was matched with a 150 nm gold top electrode and 200 nm platinum bottom electrode. As further refinements, an Al₂O₃ substrate was used and the interlayer and final interconnect layers covered only a small percentage of the active region.

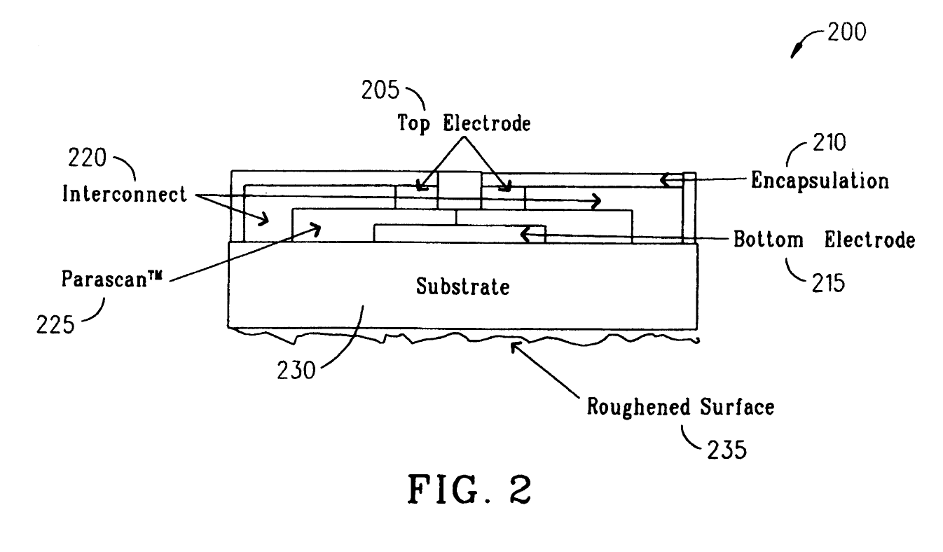

Turning now to FIG. 2, shown generally as 200, is a cross-sectional view of a tunable capacitor structure of one embodiment of the present invention with the physically rough surface. Substrate 230 may have a roughened surface 235. On a side opposite the roughened surface may be a bottom electrode 215 and a top electrode 205 with Parascan® 225 tunable dielectric material between the bottom electrode 215 and top electrode 205 with encapsulation provide at 210 and interconnect 220. Techniques for creating a roughened surface may include, but are not limited to, grinding with sand paper or a Dremel tool, using unpolished or rough cut substrate, depositing a plated material, or thick film or depositing a pattern film through a mask.

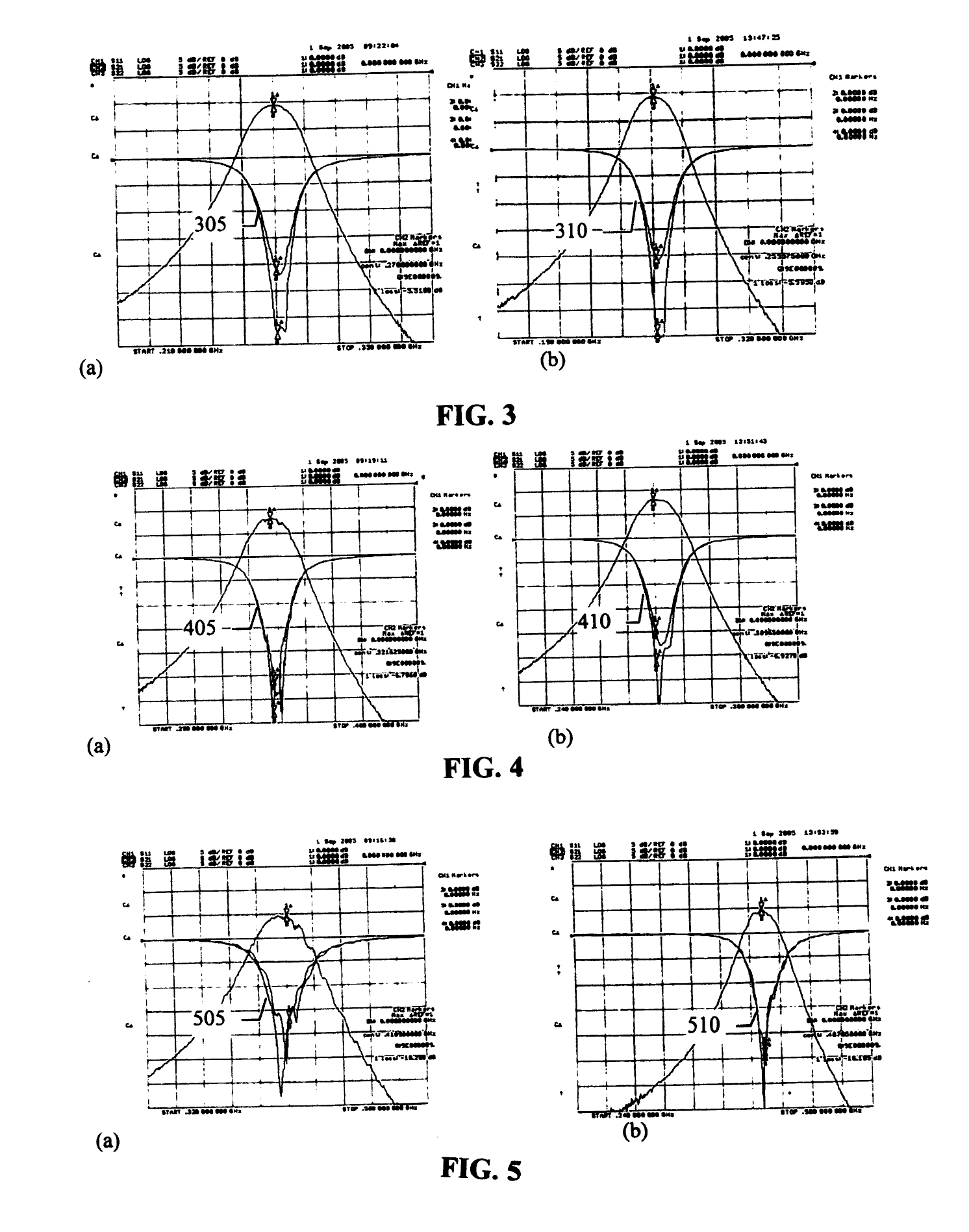

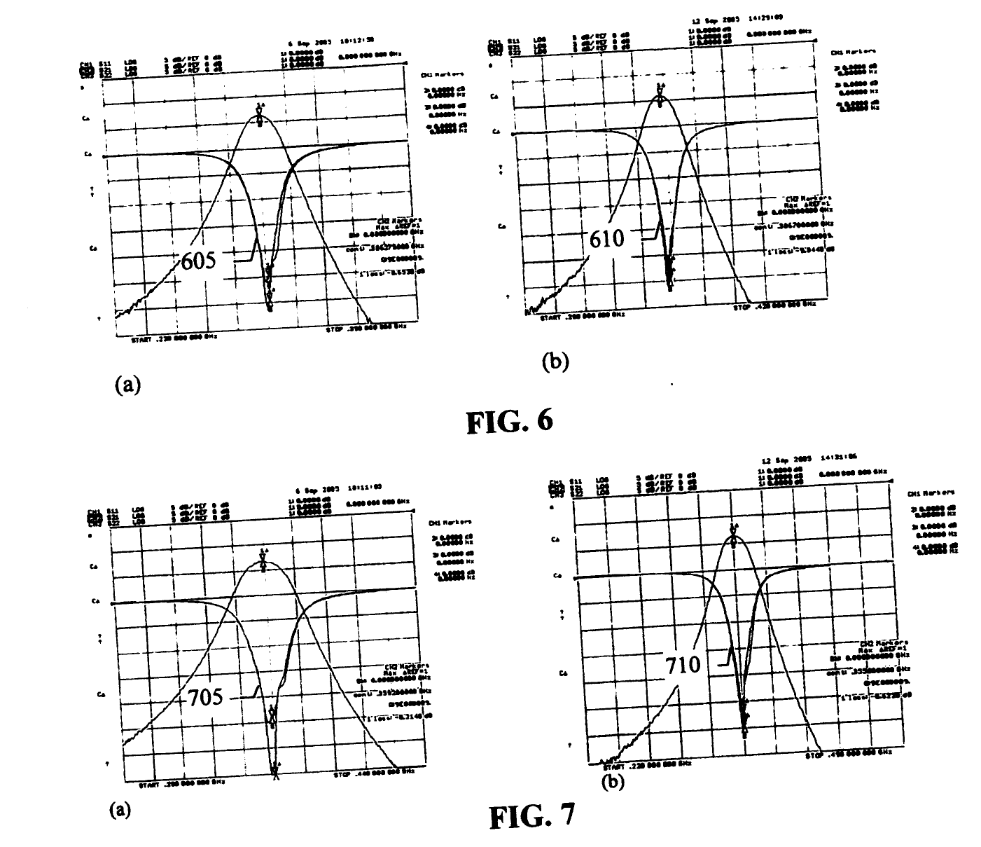

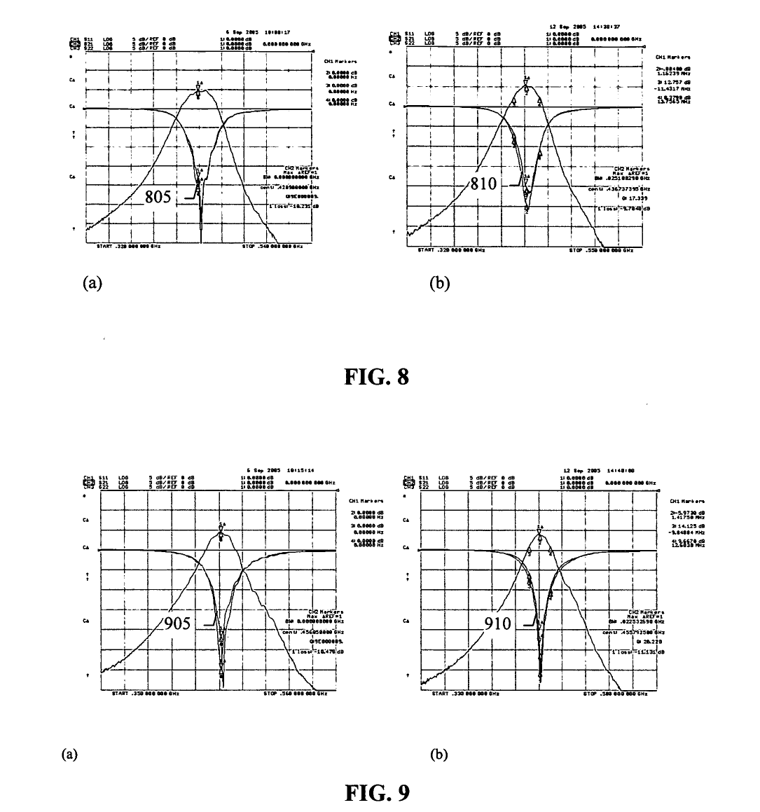

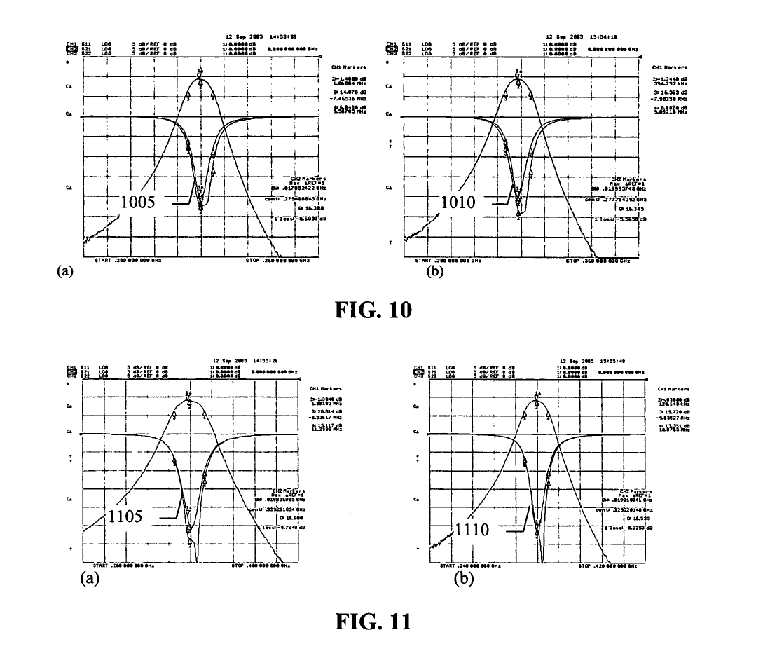

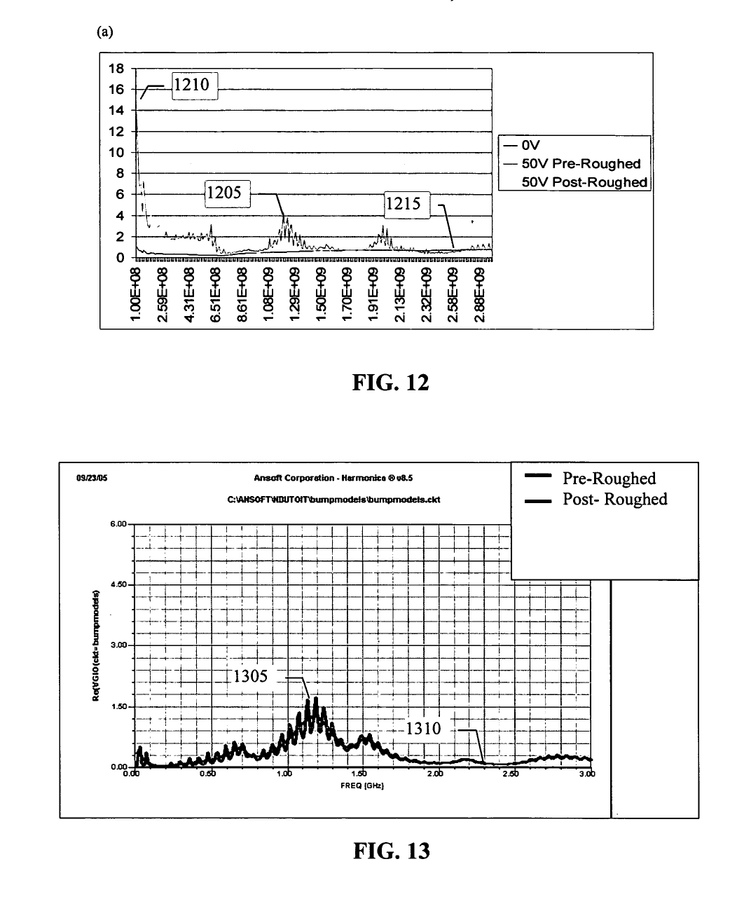

To illustrate the performance, FIG. 3 shows a filter response at 5 V bias of PLD deposited Tunable Film on MgO (a) before and (b) after roughening of backside of MgO. FIG. 4 shows a filter response at 15 V bias of PLD deposited tunable film on MgO (a) before and (b) after roughening of backside of MgO. FIG. 5 illustrates the filter response at 35 V bias of PLD deposited tunable film on MgO (a) before and (b) after roughening of backside of MgO. FIG. 6 illustrates the filter response at 5 V bias of PLD deposited tunable film on alumina (a) before and (b) after roughening of backside of alumina. FIG. 7 provides a filter response at ˜15 V bias of PLD deposited tunable film on alumina (a) before and (b) after roughening of backside of alumina. FIG. 8 provides the filter response at ˜35 V bias of PLD deposited tunable film on alumina (a) before and (b) after roughening of backside of alumina. FIG. 9 provides filter response at ˜45 V bias of PLD deposited tunable film on alumina (a) before and (b) after roughening of backside of alumina. FIG. 10 provides the filter response at ˜5 V bias of RF sputtered tunable film on alumina (b) before and (b) after roughening of backside of alumina. FIG. 11 provides the filter response at ˜15 V bias of RF sputtered tunable film on alumina before and (b) after roughening of backside of alumina. FIG. 12 graphically depicts the ESR of PLD deposited tunable film on MgO before and after roughening of the backside of MgO at 0 and 50 V of one embodiment of the present invention. FIG. 13 graphically depicts a simulation of ESR of PLD deposited tunable film on MgO before and after roughening of backside of MgO at 50 V. In this example, roughening was simulated by assigning a high acoustic loss tangent to the MgO layer.

Throughout the aforementioned description, BST has been used as a tunable dielectric material that may be used in a tunable dielectric capacitor of the present invention. However, the assignee of the present invention, Paratek Microwave, Inc. has developed and continues to develop tunable dielectric materials that may be utilized in embodiments of the present invention and thus the present invention is not limited to using BST material. This family of tunable dielectric materials may be referred to as Parascan®.

The term Parascan® as used herein is a trademarked term indicating a tunable dielectric material developed by the assignee of the present invention. Parascan® tunable dielectric materials have been described in several patents. Barium strontium titanate (BaTiO3-SrTiO3), also referred to as BSTO, is used for its high dielectric constant (200-6,000) and large change in dielectric constant with applied voltage (25-75 percent with a field of 2 Volts/micron). Tunable dielectric materials including barium strontium titanate are disclosed in U.S. Pat. No. 5,312,790 to Sengupta, et al. entitled “Ceramic Ferroelectric Material”; U.S. Pat. No. 5,427,988 by Sengupta, et al. entitled “Ceramic Ferroelectric Composite Material-BSTO—MgO”; U.S. Pat. No. 5,486,491 to Sengupta, et al. entitled “Ceramic Ferroelectric Composite Material-BSTO—ZrO2”; U.S. Pat. No. 5,635,434 by Sengupta, et al. entitled “Ceramic Ferroelectric Composite Material-BSTO-Magnesium Based Compound”; U.S. Pat. No. 5,830,591 by Sengupta, et al. entitled “Multilayered Ferroelectric Composite Waveguides”; U.S. Pat. No. 5,846,893 by Sengupta, et al. entitled “Thin Film Ferroelectric Composites and Method of Making”; U.S. Pat. No. 5,766,697 by Sengupta, et al. entitled “Method of Making Thin Film Composites”; U.S. Pat. No. 5,693,429 by Sengupta, et al. entitled “Electronically Graded Multilayer Ferroelectric Composites”; U.S. Pat. No. 5,635,433 by Sengupta entitled “Ceramic Ferroelectric Composite Material BSTO—ZnO”; U.S. Pat. No. 6,074,971 by Chiu et al. entitled “Ceramic Ferroelectric Composite Materials with Enhanced Electronic Properties BSTO Mg Based Compound-Rare Earth Oxide”. These patents are incorporated herein by reference. The materials shown in these patents, especially BSTO—MgO composites, show low dielectric loss and high tunability. Tunability is defined as the fractional change in the dielectric constant with applied voltage.

Barium strontium titanate of the formula BaxSr1−xTiO3 is a preferred electronically tunable dielectric material due to its favorable tuning characteristics, low Curie temperatures and low microwave loss properties. In the formula BaxSr1−xTiO3, x can be any value from 0 to 1, preferably from about 0.15 to about 0.6. More preferably, x is from 0.3 to 0.6.

Other electronically tunable dielectric materials may be used partially or entirely in place of barium strontium titanate. An example is BaxCa1−xTiO3, where x is in a range from about 0.2 to about 0.8, preferably from about 0.4 to about 0.6. Additional electronically tunable ferroelectrics include PbxZr1−xTiO3 (PZT) where x ranges from about 0.0 to about 1.0, PbxZr1−xSrTiO3 where x ranges from about 0.05 to about 0.4, KTaxNb1−xO3 where x ranges from about 0.0 to about 1.0, lead lanthanum zirconium titanate (PLZT), PbTiO3, BaCaZrTiO3, NaNO3, KNbO3, LiNbO3, LiTaO3, PbNb2O6, PbTa2O6, KSr(NbO3) and NaBa2(NbO3)5KH2PO4, and mixtures and compositions thereof. Also, these materials can be combined with low loss dielectric materials, such as magnesium oxide (MgO), aluminum oxide (Al2O3), and zirconium oxide (ZrO2), and/or with additional doping elements, such as manganese (MN), iron (Fe), and tungsten (W), or with other alkali earth metal oxides (i.e. calcium oxide, etc.), transition metal oxides, silicates, niobates, tantalates, aluminates, zirconnates, and titanates to further reduce the dielectric loss.

In addition, the following U.S. patents and patent applications, assigned to the assignee of this application, disclose additional examples of tunable dielectric materials: U.S. Pat. No. 6,514,895, entitled “Electronically Tunable Ceramic Materials Including Tunable Dielectric and Metal Silicate Phases”; U.S. Pat. No. 6,774,077, entitled “Electronically Tunable, Low-Loss Ceramic Materials Including a Tunable Dielectric Phase and Multiple Metal Oxide Phases”; U.S. Pat. No. 6,737,179 filed Jun. 15, 2001, entitled “Electronically Tunable Dielectric Composite Thick Films And Methods Of Making Same; U.S. Pat. No. 6,617,062 entitled “Strain-Relieved Tunable Dielectric Thin Films”; U.S. Pat. No. 6,905,989, filed May 31, 2002, entitled “Tunable Dielectric Compositions Including Low Loss Glass”; U.S. patent application Ser. No. 10/991,924, filed Nov. 18, 2004, entitled “Tunable Low Loss Material Compositions and Methods of Manufacture and Use Therefore” These patents and patent applications are incorporated herein by reference.

The tunable dielectric materials can also be combined with one or more non-tunable dielectric materials. The non-tunable phase(s) may include MgO, MgAl2O4, MgTiO3, Mg2SiO4, CaSiO3, MgSrZrTiO6, CaTiO3, Al2O3, SiO2 and/or other metal silicates such as BaSiO3 and SrSiO3. The non-tunable dielectric phases may be any combination of the above, e.g., MgO combined with MgTiO3, MgO combined with MgSrZrTiO6, MgO combined with Mg2SiO4, MgO combined with Mg2SiO4, Mg2SiO4 combined with CaTiO3 and the like.

Additional minor additives in amounts of from about 0.1 to about 5 weight percent can be added to the composites to additionally improve the electronic properties of the films. These minor additives include oxides such as zirconnates, tannates, rare earths, niobates and tantalates. For example, the minor additives may include CaZrO3, BaZrO3, SrZrO3, BaSnO3, CaSnO3, MgSnO3, Bi2O 3/2SnO2, Nd2O3, Pr7O11, Yb2O3, Ho2O3, La2O3, MgNb2O6, SrNb2O6, BaNb2O6, MgTa2O6, BaTa2O6 and Ta2O3.

Films of tunable dielectric composites may comprise Ba1−xSrxTiO3, where x is from 0.3 to 0.7 in combination with at least one non-tunable dielectric phase selected from MgO, MgTiO3, MgZrO3, MgSrZrTiO6, Mg2SiO4, CaSiO3, MgAl2O4, CaTiO3, Al2O3, SiO2, BaSiO3 and SrSiO3. These compositions can be BSTO and one of these components, or two or more of these components in quantities from 0.25 weight percent to 80 weight percent with BSTO weight ratios of 99.75 weight percent to 20 weight percent.

The electronically tunable materials may also include at least one metal silicate phase. The metal silicates may include metals from Group 2A of the Periodic Table, i.e., Be, Mg, Ca, Sr, Ba and Ra, preferably Mg, Ca, Sr and Ba. Preferred metal silicates include Mg2SiO4, CaSiO3, BaSiO3 and SrSiO3. In addition to Group 2A metals, the present metal silicates may include metals from Group 1A, i.e., Li, Na, K, Rb, Cs and Fr, preferably Li, Na and K. For example, such metal silicates may include sodium silicates such as Na2SiO3 and NaSiO3-5H2O, and lithium-containing silicates such as LiAlSiO4, Li2SiO3 and Li4SiO4. Metals from Groups 3A, 4A and some transition metals of the Periodic Table may also be suitable constituents of the metal silicate phase. Additional metal silicates may include Al2Si2O7, ZrSiO4, KalSi3O8, NaAlSi308, CaAl2Si2O8, CaMgSi2O6, BaTiSi3O9 and Zn2SiO4. The above tunable materials can be tuned at room temperature by controlling an electric field that is applied across the materials.

In addition to the electronically tunable dielectric phase, the electronically tunable materials can include at least two additional metal oxide phases. The additional metal oxides may include metals from Group 2A of the Periodic Table, i.e., Mg, Ca, Sr, Ba, Be and Ra, preferably Mg, Ca, Sr and Ba. The additional metal oxides may also include metals from Group 1A, i.e., Li, Na, K, Rb, Cs and Fr, preferably Li, Na and K. Metals from other Groups of the Periodic Table may also be suitable constituents of the metal oxide phases. For example, refractory metals such as Ti, V, Cr, Mn, Zr, Nb, Mo, Hf, Ta and W may be used. Furthermore, metals such as Al, Si, Sn, Pb and Bi may be used. In addition, the metal oxide phases may comprise rare earth metals such as Sc, Y, La, Ce, Pr, Nd and the like.

The additional metal oxides may include, for example, zirconnates, silicates, titanates, aluminates, stannates, niobates, tantalates and rare earth oxides. Preferred additional metal oxides include Mg2SiO4, MgO, CaTiO3, MgZrSrTiO6, MgTiO3, MgAl2O4, WO3, SnTiO4, ZrTiO4, CaSiO3, CaSnO3, CaWO4, CaZrO3, MgTa2O6, MgZrO3, MnO2, PbO, Bi2O3 and La2O3. Particularly preferred additional metal oxides include Mg2SiO4, MgO, CaTiO3, MgZrSrTiO6, MgTiO3, MgAl2O4, MgTa2O6 and MgZrO3.

The additional metal oxide phases are typically present in total amounts of from about 1 to about 80 weight percent of the material, preferably from about 3 to about 65 weight percent, and more preferably from about 5 to about 60 weight percent. In one preferred embodiment, the additional metal oxides comprise from about 10 to about 50 total weight percent of the material. The individual amount of each additional metal oxide may be adjusted to provide the desired properties. Where two additional metal oxides are used, their weight ratios may vary, for example, from about 1:100 to about 100:1, typically from about 1:10 to about 10:1 or from about 1:5 to about 5:1. Although metal oxides in total amounts of from 1 to 80 weight percent are typically used, smaller additive amounts of from 0.01 to 1 weight percent may be used for some applications.

The additional metal oxide phases can include at least two Mg-containing compounds. In addition to the multiple Mg-containing compounds, the material may optionally include Mg-free compounds, for example, oxides of metals selected from Si, Ca, Zr, Ti, Al and/or rare earths.

While the present invention has been described in terms of what are at present believed to be its preferred embodiments, those skilled in the art will recognize that various modifications to the disclose embodiments can be made without departing from the scope of the invention as defined by the following claims.

1. An apparatus, comprising:
a voltage tunable capacitor including a substrate, wherein a surface of said substrate opposite said voltage tunable capacitor is made physically rough such that reflections off a surface internal to said substrate are scattered and dissipated.

2. The apparatus of claim 1, wherein said surface of said substrate opposite said voltage tunable capacitor is made physically rough by using abrasion or other mechanical techniques.

3. The apparatus of claim 1, wherein said surface of said substrate opposite said voltage tunable capacitor is made physically rough by creating a rough surface through deposition of a material on the surface in a non-uniform manner such as evaporating a rough metal or dielectric.

4. The apparatus of claim 1, wherein said surface of said substrate opposite said voltage tunable capacitor is made physically rough by plating metals under what would otherwise be considered a poor plating condition leading to a rough surface.

5. (canceled)

6. The apparatus of claim 1, wherein said voltage tunable capacitor comprises:
a bottom electrode layer adjacent said substrate;
a voltage tunable dielectric layer adjacent said bottom electrode layer, said voltage tunable dielectric layer including an active region;
a top electrode adjacent said voltage tunable dielectric layer;
a final interconnect layer connected to said top electrode via an interlayer; and
wherein said top and bottom electrodes are at a predetermined thickness such that a desired high fundamental acoustic resonance is obtained.

7. A method of reducing ripples in a voltage tunable capacitor, comprising:
making a surface of a substrate opposite said voltage tunable capacitor physically rough such that reflections off a surface internal to said substrate are scattered and dissipated.

8. The method of claim 7, further comprising making said surface of said substrate opposite said voltage tunable capacitor physically rough by using abrasion or other mechanical techniques.

9. The method of claim 7, further comprising making said surface of said substrate opposite said voltage tunable capacitor physically rough by creating a rough surface through deposition of a material on the surface in a non-uniform manner such as evaporating a rough metal or dielectric.

10. The method of claim 7, further comprising making said surface of said substrate opposite said voltage tunable capacitor physically rough by plating metals under what would otherwise be considered a poor plating condition leading to a rough surface.

11. (canceled)

12. The method of claim 7, wherein said voltage tunable capacitor comprises:
a bottom electrode layer adjacent said substrate;
a voltage tunable dielectric layer adjacent said bottom electrode layer, said voltage tunable dielectric layer including an active region;
a top electrode adjacent said voltage tunable dielectric layer;
a final interconnect layer connected to said top electrode via an interlayer; and
wherein said top and bottom electrodes are at a predetermined thickness such that a desired high fundamental acoustic resonance is obtained.

13. A method of manufacturing a voltage tunable capacitor with reduced ripples, comprising:
manufacturing a surface of a substrate opposite said voltage tunable capacitor physically rough such that reflections off a surface internal to said substrate are scattered and dissipated.

14. The method of manufacturing of claim 13, further comprising manufacturing said surface of said substrate opposite said voltage tunable capacitor physically rough by using abrasion or other mechanical techniques.

15. The method of manufacturing of claim 13, further comprising manufacturing said surface of said substrate opposite said voltage tunable capacitor physically rough by creating a rough surface through deposition of a material on the surface in a non-uniform manner such as evaporating a rough metal or dielectric.

16. The method of claim manufacturing of claim 13, further comprising manufacturing said surface of said substrate opposite said voltage tunable capacitor physically rough by plating metals under what would otherwise be considered a poor plating condition leading to a rough surface.

17. (canceled)

18. The method of manufacturing of claim 13, further comprising manufacturing said voltage tunable capacitor with:
a bottom electrode layer adjacent said substrate;
a voltage tunable dielectric layer adjacent said bottom electrode layer, said voltage tunable dielectric layer including an active region;
a top electrode adjacent said voltage tunable dielectric layer;
a final interconnect layer connected to said top electrode via an interlayer; and
wherein said top and bottom electrodes are at a predetermined thickness such that a desired high fundamental acoustic resonance is obtained.
